(19) United States
(12) Patent Application Publication
(10) Pub. No.: US 2015/0028314 A1
(43) Pub. Date: Jan. 29, 2015

(54) ORGANIC ELECTROLUMINESCENT LIGHT EMITTING DEVICE AND METHOD FOR MANUFACTURING SAME

(71) Applicant: PANASONIC CORPORATION, Osaka (JP)

(72) Inventor: Hirofumi Kubota, Osaka (JP)

(21) Appl. No.: 14/376,694

(22) PCT Filed: Feb. 8, 2013
(86) PCT No.: PCT/JP2013/000688

§ 371 Date: Aug. 5, 2014

(30) Foreign Application Priority Data
Feb. 8, 2012 (JP) 2012-025359

(51) Int. Cl. H01L 51/52; H01L 27/32; H01L 51/56

(52) U.S. Cl. CPC H01L 51/5268; H01L 51/5246; H01L 51/5259; H01L 51/56; H01L 27/3204
USPC 257/40; 438/29

(57) ABSTRACT

Provided is an organic electroluminescent light emitting device that can prevent moisture and/or oxygen permeation to thereby suppress degradation and that has increased light extraction efficiency. The organic electroluminescent light emitting device includes an organic electroluminescent element including an optically transparent first electrode, a light emitting function layer composed of two or more layers including a light emitting layer, and a second electrode, which are stacked on a surface of an optically transparent substrate in that order. A functional scattering section is provided in contact with at least part of an end face of the optically transparent substrate. The functional scattering section is foamed of a resin composition including a scattering body having moisture absorption property and/or oxygen absorption property. With the functional scattering section, moisture and/or oxygen can be prevented from entering inside the device and the light extraction efficiency can be enhanced.

### TECHNICAL FIELD

The present invention relates to an organic electroluminescent light emitting device having an organic electroluminescent element, and a method for manufacturing the same.

### BACKGROUND ART

Recently, an organic electroluminescent element (hereinafter, also referred to as “organic EL element”) has been applied for use in a lighting panel or the like. An example of a known organic EL element is formed by stacking: a first electrode (anode) with optical transparency; a light emitting function layer composed of two or more layers including a light emitting layer; and a second electrode (cathode) on a surface of an optically transparent substrate in that order. An organic EL element is configured so that a light emitting layer emits light in accordance with a voltage applied between an anode and a cathode, and the light is taken out through the optically transparent electrode and substrate. An organic electroluminescent light emitting device (hereinafter, also referred to as “organic EL light emitting device”) is a device formed by sealing an organic EL element as described above as a light emitting element with a proper sealing member.

### CITATION LIST

### Patent Literature

PATENT LITERATURE 1: JP2005-183352A

PATENT LITERATURE 2: JP2005-158369A

### SUMMARY OF INVENTION

### Technical Problem

In an organic EL light emitting device, in general, the light emitted by a light emitting layer is weakened due to absorption by a substrate, total reflection at a layer interface, or the like. For that reason, the intensity of the light emitted outward is small compared with a theoretical light intensity. Therefore, one of problems of the device has been to increase a light extraction efficiency of an organic EL element to increase the brightness.

It has also been tried to provide an organic EL light emitting device in which two or more organic EL elements are arranged in a plane in order to enlarge a total light emitting area. The larger the light emitting area becomes, the larger area the light is emitted from as well as the stronger the light intensity becomes. Therefore, enlarging the light emitting area increases the usefulness for an illumination device. For example, Patent Literatures 1 and 2 disclose illumination devices in each of which two or more organic EL elements are arranged side by side.

Incidentally, for an organic EL light emitting device, it is important to prevent moisture and oxygen from entering the inside thereof. Moisture or oxygen entering a sealed region of an organic EL light emitting device possibly deteriorates the organic EL light emitting device and causes a trouble such as insufficient light emission, and thus the reliability of the organic EL light emitting device is decreased. Particularly, in an organic EL light emitting device that employs a material having a comparatively high moisture and/or oxygen permeability such as plastic, moisture and/or oxygen possibly enters the inside of the device through these materials.

Besides, when an organic EL light emitting device is formed by coupling two or more organic EL elements, a non-light emitting area may be formed at the coupling region because this region may include a gap or the light becomes hardly to reach this region, or the like, which leads the reduction of light intensity. Therefore, there is a concern that the uniformity of the intensity of light in a plane is decreased and the brightness is decreased in total. Thus, it has been desired to obtain a further strong and natural light.

The present invention has been achieved in view of the above circumstances, and an object thereof is to provide an organic electroluminescent light emitting device that can prevent moisture and/or oxygen permeation to thereby suppress degradation and that has an increased light extraction efficiency, and a method for manufacturing the organic electroluminescent light emitting device.

### Solution to Problem

An organic electroluminescent light emitting device of the invention includes an organic electroluminescent element and a functional scattering section. In the organic electroluminescent element, a first electrode with optical transparency, a light emitting function layer composed of two or more layers including a light emitting layer, and a second electrode are stacked on a surface of an optically transparent substrate in that order. The functional scattering section is provided in contact with at least part of an end face of the optically transparent substrate. The functional scattering section is formed of a resin composition that includes scattering bodies having at least one of moisture absorption property and oxygen absorption property.

In a preferred embodiment of the organic electroluminescent light emitting device, the functional scattering section contains toning dye that controls light color emitted from the end face of the optically transparent substrate.

In a preferred embodiment of the organic electroluminescent light emitting device, the toning dye is dye for converting the light emitted from the end face of the optically transparent substrate into white light.

In a preferred embodiment of the organic electroluminescent light emitting device, the toning dye contains at least blue pigment.

In a preferred embodiment of the organic electroluminescent light emitting device, the organic electroluminescent element is provided two or more in a direction perpendicular to a stacking direction of an organic electroluminescent element, and the functional scattering section is formed between optically transparent substrates of adjacent organic electroluminescent elements.

In a preferred embodiment of the organic electroluminescent light emitting device, the optically transparent substrate is composed of a glass substrate and a plastic layer formed over at least part of a surface of the glass substrate, and the functional scattering section is in contact with an end face of the plastic layer.

A method for manufacturing organic electroluminescent light emitting device of the invention includes: an arranging step of arranging, on a surface of a support base, two or more organic electroluminescent elements each of which includes a first electrode with optical transparency, a light emitting function layer composed of two or more layers including a light emitting layer, and a second electrode, which are stacked on a surface of an optically transparent substrate in that order; a filling step of filling a resin composition including scattering bodies between optically transparent substrates of adjacent organic electroluminescent elements; and a curing step of curing the resin composition.

In a preferred embodiment of the method for manufacturing organic electroluminescent light emitting device, the scattering bodies have at least one of moisture absorption property and oxygen absorption property.

In a preferred embodiment of the method for manufacturing organic electroluminescent light emitting device, the resin composition includes thermoset resin, and the curing step includes heating the resin composition to cure the resin composition.

In a preferred embodiment of the method for manufacturing organic electroluminescent light emitting device, the resin composition includes ultraviolet curable resin, and the curing step includes irradiating the resin composition with ultraviolet to cure the resin composition.

### Advantageous Effects of Invention

According to the present invention, since a functional scattering section is provided, it is possible to obtain an organic electroluminescent light emitting device that can prevent moisture and/or oxygen permeation to thereby suppress degradation and that has an increased light extraction efficiency.

### BRIEF DESCRIPTION OF DRAWINGS

FIG. 1 is a sectional diagram illustrating an example according to an embodiment of an organic electroluminescent light emitting device;

FIG. 2 is a sectional diagram illustrating an example according to an embodiment of an organic electroluminescent light emitting device;

FIG. 3 is a sectional diagram illustrating an example according to an embodiment of an organic electroluminescent light emitting device;

FIG. 4 is a sectional diagram illustrating an example according to an embodiment of an organic electroluminescent light emitting device; and

FIG. 5 is a sectional diagram illustrating an example according to an embodiment of an organic electroluminescent light emitting device.

### DESCRIPTION OF EMBODIMENTS

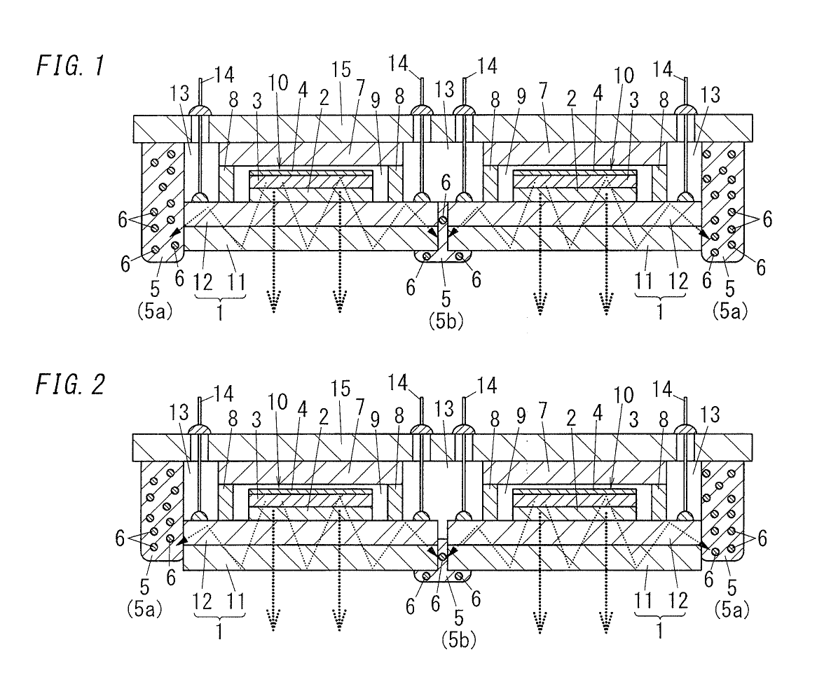

FIG. 1 shows an example of an embodiment of an organic electroluminescent light emitting device (organic EL light emitting device). The organic EL light emitting device includes at least one organic electroluminescent element (organic EL element) 10. In the organic EL element 10, a first electrode 2 with optical transparency, a light emitting function layer 3 composed of two or more layers including a light emitting layer, and a second electrode 4 are stacked on a surface of an optically transparent substrate 1 in that order. In the organic EL light emitting device of the embodiment of FIG. 1, the organic electroluminescent element 10 is provided two or more. In this figure, the organic EL element 10 is provided two and they are arranged in a direction perpendicular to a stacking direction of an organic EL element 10, but may be provided three or more. In fact, in the organic EL light emitting device, two or more organic EL elements 10 may be arranged lengthwise and breadthwise in a plane perpendicular to the stacking direction. Arranging (tiling) two or more organic EL elements 10 can enlarge the light emitting area, which enables the device to emit light in a large area as well as to emit light with increased intensity. Therefore, the device becomes useful as an illumination device, in particular, as a panel lighting device. In the organic EL light emitting device, the organic EL elements 10 may be arranged in one direction in a line, not in a plane.

In the organic EL element 10, usually, the first electrode 2 functions as an anode and the second electrode 4 functions as a cathode, but they may be inversed. The second electrode 4 may have light reflection property. In this configuration, the light emitted from the light emitting layer toward the second electrode 4 is to be reflected by the second electrode 4 and can be taken out from the optically transparent substrate 1 side. The light emitting function layer 3 is a layer that is configured to emit light, and includes some layers selected from a hole injection layer, a hole transport layer, a light emitting layer, an electron transport layer, an electron injection layer, an intermediate layer, and the like.

In this embodiment, the optically transparent substrate 1 includes a plastic layer 12 in a surface of the substrate. The optically transparent substrate 1 of this embodiment is composed of a glass substrate 11 and the plastic layer 12. The plastic layer 12 is formed on an organic EL element 10 side surface of the glass substrate 11. The plastic layer 12 may be formed over the entire surface of the glass substrate 11, or may be formed on at least part of the surface of the glass substrate 11. The plastic layer 12 may be provided at a region (a light emitting structure stacking region) on which the first electrode 2 and the light emitting function layer 3 are stacked. The optically transparent substrate 1 may be formed of what is called a composite substrate.

The plastic layer 12 may be composed of a molded article (such as a sheet and a film) formed by shaping and curing synthetic resin of plastic raw material, and may be adhered to the glass substrate 11. The plastic layer 12 may be formed of plastic material such as PET (polyethylene terephthalate) and PEN (polyethylene naphthalate). Alternately, the plastic layer 12 may be formed by applying resin material to the glass substrate 11 and curing the resin material. The resin material used for the application and curing may be epoxy- or acrylic-thermoset or ultraviolet-curable resin. The plastic layer 12 provided in the surface of the optically transparent substrate 1 can relax the difference in refractive index between the glass substrate 11 and the first electrode 2, thereby increasing the light extraction efficiency. That is, the light emitted from the light emitting layer reaches the substrate directly or via reflection, but the light may be subjected to a total reflection and not be extracted outside if the difference in refractive index is large at the interface. Therefore, interposing a plastic layer 12 between the glass substrate 11 and the first electrode 2 makes it possible to suppress the occurrence of the total reflection and to thereby enhance the light extraction efficiency. One example is to provide a plastic layer 12 having a refractive index between those of the glass substrate 11 and the first electrode 2. This configuration makes it possible to reduce the difference in the refractive index and to thereby suppress the occurrence of the total reflection to enhance the light extraction efficiency. Another example is to provide, on the surface of the glass substrate 11, a plastic layer 12 for scattering the light. In this configuration, the plastic layer 12 scatters the light that reaches the surface of the optically transparent substrate 1, thereby suppressing the occurrence of the total reflection, and accordingly more light can be extracted outside.

In the optically transparent substrate 1, a light extracting structure for increasing light extraction efficiency may be provided between the glass substrate 11 and the plastic layer 12. This structure can further increase the light extraction efficiency. Examples of the light extracting structure include irregularity formed in the surface of the glass substrate 11; and a light scattering layer that contains light scattering materials and is formed on the surface of the glass substrate 11. Furthermore, a light extracting section such as a light scattering layer may be provided on an outside surface of the optically transparent substrate 1.

In the organic EL element 10, a protection substrate 7 is arranged to face the optically transparent substrate 1 so as to seal a stacked structure composed of the first electrode 2, the light emitting function layer 3 and the second electrode 4. The protection substrate 7 may be formed of a substrate that is resistant to moisture and/or oxygen permeation, such as a glass substrate. The protection substrate 7 is adhered to the optically transparent substrate 1 by a sealing resin member 8 so as to form a sealed space 9 inside a region (sealed region) sealed with the protection substrate 7. Desiccant may be provided in the sealed space 9. With this configuration, even if moisture enters the sealed space 9, the moisture can be absorbed by the desiccating agent. The sealed space 9 may be filled with sealing material.

In the organic EL light emitting device of the embodiment, the two or more organic EL elements 10 are fixed to a support base 15 which is arranged on the opposite side of the organic EL elements 10 from the optically transparent substrates 1. Using the support base 15 makes it possible to easily arrange the organic EL elements 10 in a line or in a plane. Furthermore, the support base 15 can enhance the physical strength of the organic EL light emitting device. The support base 15 may be formed of a material having a high fixation property such as a metal plate and a resin plate. Examples of the fixation of the organic EL element 10 include adhesion by an adhesive agent, a double-sided tape or the like, screw fastening, and fitting. In this embodiment, further, an inter-element space 13 is formed between the organic EL elements 10, as a space enclosed by the support base 15 and the optically transparent substrate 1.

The support base 15 is provided with electric wires 14 extending from the outside of the light emitting device into the inside thereof. Further, electrode pads (a first electrode pad and a second electrode pad) are formed on ends of a first electrode 2 side surface of each of the optically transparent substrates 1, and are electrically connected to a first electrode 2 and a second electrode 4, respectively. The electric wires 14 are connected to respective electrode pads inside the device so that positive sides (anode) of them correspond to each other and negative sides (cathode) of them correspond to each other. Each of the electrode pads extends from the inside of the region (sealed region) sealed with the protection substrate 7 to the outside thereof. The electrode pads may be provided on a surface of a plastic layer 12 in the inter-element space 9. Note that illustration of the electrode pads is omitted in FIG. 1. The electric wires 14 may be fixed to the electrode pads and the support member 15 with a proper material such as solder and curable resin. When a voltage is applied between the first electrode 2 and the second electrode 4 through the electric wires 14 and the electrode pads, holes and electrons are coupled in the light emitting layer of the light emitting function layer 3, thereby emitting light.

In the organic EL light emitting device of the embodiment, a functional scattering section 5 is provided in contact with at least part of an end face of the optically transparent substrate 1. The functional scattering section 5 is formed of a resin composition including scattering bodies 6 having at least one of moisture absorption property and oxygen absorption property. In the embodiment of the organic EL light emitting device that includes two or more organic EL elements 10 shown in FIG. 1, a lateral side functional scattering section 5a is provided on an outside end face of an optically transparent substrate 1 of an organic EL element 10 that is arranged at a lateral end of the device. The lateral side functional scattering section 5a is provided in a manner that the entire end face of the optically transparent substrate 1 is covered with the lateral side functional scattering section 5a. The lateral side functional scattering section 5a is adhered to the support member 15 in contact therewith and also is adhered to the end face of the optically transparent substrate 1 in contact therewith. The lateral side functional scattering section 5a is, preferably, provided so as to surround two or more organic EL elements 10 at a lateral end of the organic EL light emitting device. Surrounded by the lateral side functional scattering section 5a, at least end faces of optically transparent substrates 1 are covered at the lateral end of the device. In this embodiment, since the lateral side functional scattering section 5a is in contact with the support member 15, a lateral side of the organic EL element 10 arranged at the lateral end of the device is occluded by the lateral side functional scattering section 5a. With this configuration, the plastic layer 12 of the organic EL element 10 arranged at the lateral end is isolated from and also is not communicated with the outside space.

In the embodiment, an inter-element functional scattering section 5b as the functional scattering section 5 is formed between optically transparent substrates 1 of adjacent organic EL elements 10, 10. That is, the inter-element functional scattering section 5b is provided to fill a gap between the optically transparent substrates 1, 1. The inter-element functional scattering section 5b can be said to be in contact with an end face of an optically transparent substrate 1 at an end of the optically transparent substrate 1. In the embodiment, the inter-element functional scattering section 5b is provided in a gap between adjacent optically transparent substrates 1, 1 so as to fill the whole gap from one surface of an optically transparent substrate 1 to the other surface thereof. However, the inter-element functional scattering section 5b may be provided partially in the gap (partially in the stacking direction) between the optically transparent substrates 1, 1. In this case, preferably, the inter-element functional scattering section 5b is provided in a region at least outer side compared with the plastic layer 12 in the stacking direction. With this configuration, since the gap between the optically transparent substrates 1, 1 is filled with the inter-element functional scattering section 5b, the inter-element space 13 is not communicated with the outside space and as a result the plastic layer 12 can be isolated from the outside. In this embodiment, moisture can be blocked also by the sealing resin member 8. Thus, permeation of moisture and oxygen into the sealed space 9 can be doubly blocked by the functional scattering section a and the sealing resin member 8. In the embodiment of FIG. 1, the resin composition is filled in the gap so as to be overflowed therefrom to an outer surface of the optically transparent substrate 1, so that the inter-element functional scattering section 5b is also formed on an outer side surface of the glass substrate 11 so as to cover the gap between the optically transparent substrates 1, 1. As a result, a larger amount of the functional scattering section 5 can be provided in a boundary part between the organic EL elements 10.

As mentioned above, an element in an organic EL light emitting device is possibly deteriorated by the permeation of moisture and/or oxygen. Particularly, in a device that employs an optically transparent substrate 1 with a plastic layer 12, moisture and/or oxygen possibly enters the inside of the device through the plastic layer 12. That is, if the plastic layer 12 is exposed outward, moisture and/or oxygen may enter the inside of the plastic layer 12 through the exposed region, and the moisture and/or oxygen may enter the inside of the sealed region and/or reach the light emitting function layer 3 through the plastic layer 12. Then, the entered moisture and/or oxygen possibly deteriorates the element. On the contrary, in the organic EL light emitting device of the embodiment, the plastic layer 12 is not exposed outward and is isolated therefrom by virtue of the functional scattering section 5. In detail, an outside end face of a plastic layer 12 arranged at a lateral end of the light emitting device is isolated from the outside space by the lateral side functional scattering section 5a. In addition, an end face of a plastic layer 12 at an inner side of the light emitting device is isolated from the outside space by the inter-element functional scattering section 5b. The functional scattering section 5 includes scattering bodies 6 having at least one of moisture absorption property and oxygen absorption property. Thus, moisture and/or oxygen that attempts to enter the inside of the device through the functional scattering section 5 is to be absorbed by the scattering bodies 6. As a result, moisture and/or oxygen is hard to reach the plastic layer 12. It is therefore possible to prevent moisture and/or oxygen from entering the device through the plastic layer 12 and to thereby suppress degradation of the element.

The functional scattering section 5 includes the scattering bodies 6 that are configured to scatter the light. Therefore, the light propagating inside the optically transparent substrate 1 can be scattered by the functional scattering section 5 and to be extracted outside, and thereby the light extraction efficiency can be enhanced.

The light emitted from a light emitting layer is, in general, taken out through the optically transparent substrate 1, but the light that enters the optically transparent substrate 1 with a certain angle (critical angle) or more is to be subject to a total reflection and to propagate inside the optically transparent substrate 1 as a guided light. Part of the guided light is to be emitted outside from the optically transparent substrate 1 and thus can be seen from the outside, but the remaining of the guided light is to be emitted laterally from the end face of the optically transparent substrate 1 and thus cannot be extracted in a visible direction. Thus, the conventional organic EL light emitting device has inferior light extraction efficiency. On the contrary, according to the organic EL light emitting device of the embodiment, the guided light propagating inside the optically transparent substrate 1 is to enter the functional scattering section 5 arranged on the end face of the optically transparent substrate 1. Then, the light is scattered by the functional scattering section 5 and is changed its propagating direction, and accordingly is to be extracted in the visible direction. As a result, the light extraction efficiency can be enhanced.

The lateral side functional scattering section 5a can scatter a guided light that reaches a lateral end of the organic EL light emitting device to take the light out, and therefore can enhance the emission intensity of the device. The inter-element functional scattering section 5b can scatter a guided light that reaches an end face of a substrate of an organic EL element 10 to take the light out, and therefore can enhance the emission intensity of the device. Note that, as mentioned above, in the organic EL light emitting device in which two or more elements are coupled, a non-light emitting area may be formed at the coupling region. The coupling region is formed around light emitting regions and looks like a dark (non-luminous) frame, and accordingly looks unattractive in design for use in a large screen by tiling organic EL elements 10. Further, in a case of using the device as a planar illumination, the non-light emitting area deteriorates uniformity of brightness and total luminous flux. On the contrary, according to the organic EL light emitting device of the embodiment, since the inter-element functional scattering section 5b is provided in the coupling region of the organic EL elements 10, it is possible to take the light out from the coupling region. It is accordingly possible to eliminate or reduce the non-light emitting area between the elements and to thereby make the gap between the elements less noticeable. Therefore, the light can be made uniform in a plane, and accordingly it is possible to obtain a natural planar light. Since the non-light emitting area can be converted into light emitting area, the total emission intensity can be increased.

The inter-element functional scattering section 5b may be provided on the outside surface of the optically transparent substrate 1 so as to extend to the vicinity of a region corresponding to a region provided with the sealing resin member 8. That is, the inter-element functional scattering section 5b may extend to the vicinity of the sealed region in a planar view. Since moisture and/or oxygen can be blocked by not only the sealing resin member 8 but also the functional scattering section 5b, it is possible to prevent the degradation of the organic EL element 10 and to increase the life of the illumination panel and the like.

In general, the further the distance is from a region on which the light emitting function layer 3 is stacked, the smaller the angle becomes between a propagating direction of the light from the light emitting layer and the surface of the optically transparent substrate 1. Therefore, the emission intensity may be weak at a boundary part between the organic EL elements 10. On the contrary, according to the structure in which the inter-element functional scattering section 5b is provided on the surface of the substrate so as to extend to a region corresponding to the sealed region, a larger amount of light can be scattered at the boundary part between the organic EL elements 10 and to thereby the reduction of light can be suppressed. Accordingly, the coupling region between the organic EL elements 10 can be further made less noticeable.

Examples of the scattering body 6 include silica gel and desiccant. These materials have moisture absorption property, and also have high dispersion property in resin composition and accordingly the functional scattering section 5 can be formed easily. AGELESS (manufactured by MITSUBISHI GAS CHEMICAL COMPANY, INC.) and EVER-FRESH (manufactured by TORISHIGE SANGYO Co., Ltd.) may be employed as a scattering body having oxygen absorption property. Both of the scattering bodies 6 having moisture absorption property and the scattering bodies 6 having oxygen absorption property can be used in mixture. It is also preferable to use scattering bodies 6 having both the moisture absorption property and the oxygen absorption property.

Incidentally, in a case where the light color emitted from the surface of the optically transparent substrate 1 is same as the light color emitted from the end face thereof, there is no problem in terms of color temperature. However, in a case where these colors are different from each other, the light emitted from the end face of the optically transparent substrate 1 is noticeable and may be bothersome. In this case, it is preferable that the functional scattering section 5 contains toning dye that controls the light color emitted from the end face of the optically transparent substrate 1. For example, the functional scattering section 5 may contain toning dye so that the light color emitted from the end face of the optically transparent substrate 1 approximates the light color emitted from the surface. With this configuration, it is possible to make less noticeable the light having a different color temperature, emitted from the end face of the optically transparent substrate 1.

Particularly, even when the light color emitted from the surface of the optically transparent substrate 1 is white, the light color emitted from the end face thereof is possibly not white. This is caused by that only the light having a wavelength within a certain range, from among the light that enters inside the optically transparent substrate 1, can propagate inside the substrate without attenuation by interference and to thereby be emitted from the end face of the optically transparent substrate 1. Because the non-white light around the optically transparent substrate 1 may be eye-catching, this kind of device may not be appropriate for illumination purpose that usually requires white light. In such a case, preferably, the toning dye is dye for converting the light emitted from the end face of the optically transparent substrate 1 into white light. With this configuration, the light emitted from the end face of the optically transparent substrate 1 can be converted into the white light and be made less noticeable, and therefore the organic electroluminescent light emitting device of this configuration is preferable for the use of illumination.

For example, even when the light color emitted from the surface of the optically transparent substrate 1 is white, the light color emitted from the end face thereof is possibly green or pale red. In this case, preferably, the toning dye contains at least blue pigment. With this configuration, the light emitted from the end face of the optically transparent substrate 1 can be converted into white light and be less noticeable. Particularly, in a case where the light color emitted from the end face of the optically transparent substrate 1 is green, it is preferable that the toning dye contains red pigment in addition to the blue pigment. In a case where the light color emitted from the end face of the optically transparent substrate 1 is red, it is preferable that the toning dye contains green pigment in addition to the blue pigment. With this configuration, the light emitted from the end face of the optically transparent substrate 1 can be readily converted into white light and be less noticeable, and therefore the organic electroluminescent light emitting device of this configuration is further preferable for the use of illumination.

A method for manufacturing the organic EL light emitting device shown in FIG. 1 is now explained.

For manufacturing the organic EL light emitting device, firstly, two or more organic EL elements 10 are arranged on a surface of the support base 15. This step is referred to as an arranging step. Each of the organic EL elements 10 may have the structure as described above, namely, may include the first electrode 2 with optical transparency, the light emitting function layer 3 composed of two or more layers including the light emitting layer, and the second electrode 4, which are stacked on the surface of the optically transparent substrate 1 in that order.

Then, the resin composition including the scattering bodies 6 is filled between the optically transparent substrates 1 of the adjacent organic EL elements 10. This step is referred to as a filling step. The resin composition can be filled by applying a paste-like resin composition to the gap from the outside surface side so as to bury the gap. It is preferable that the resin composition is supplied so as to be overflowed from the gap. With this process, the functional scattering section 5 can be easily formed on the surface of the glass substrate 11. With this configuration, since the gap is filled with the resin composition, the adjacent optically transparent substrates 1, 1 can be coupled with each other by adhesion, which makes it possible to unite the two or more optically transparent substrates 1 in a plane and to increase the fixation strength of the organic EL elements 10. Because the resin composition is filled in the gap between the optically transparent substrates 1, the inter-element space 13 among the organic EL elements 10 is enclosed and isolated from the outside space. In the embodiment of FIG. 1, the resin composition can be provided on the lateral end of the light emitting device simultaneously or continuously with the filling step. For example, the resin composition including the scattering bodies 6 may be applied to the surface of the support base 15 on the lateral side of the organic EL element 10 arranged on the lateral end. In this process, the resin composition is preferably provided in contact with the outside end face of the optically transparent substrate 1 so as to cover the end face. With this configuration, a space in the lateral end of the organic EL light emitting device is occluded and the inter-element space 13 can be made into an enclosed space.

Then, the filled resin composition is cured by an appropriate method. With this process, the resin is cured, and the functional scattering section 5 in which the scattering bodies 6 are dispersed can be formed. This step is referred to as a curing step. The inter-element functional scattering section 5b is formed by the resin composition filled between the optically transparent substrates 1, and the lateral side functional scattering section 5a is formed by the resin composition provided on the outside end face of the organic EL element 10 arranged on the lateral end of the device.

In the method for manufacturing the organic EL light emitting device, the scattering bodies 6 may not have the moisture absorption property and the oxygen absorption property. Even if the scattering bodies 6 do not have the moisture absorption property and the oxygen absorption property, it is possible to increase the light extraction efficiency by forming the functional scattering section 5 inside the gap of the coupling region between the elements. Also, it is possible to obtain a natural light. Note that the scattering bodies 6 having at least one of the moisture absorption property and the oxygen absorption property can prevent moisture and/or oxygen from entering the inside of the device to provide the moisture prevention effect and/or the oxygen prevention effect. It is therefore desirable to employ such scattering bodies 6 that have at least one of the moisture absorption property and the oxygen absorption property.

The resin composition may include thermoset resin or ultraviolet curable resin. With such resins, the resin composition can be cured easily and the functional scattering section 5 can be formed easily.

With the thermostat resin, the curing step may be heating the resin composition to cure the resin composition. The temperature for the heating is, preferably, set to lower than the heatproof temperature of the plastic layer 12. If the temperature for the heating is too high, the plastic layer 12 is possibly to be melted. The resin composition may include, in addition to the resin as the main component, an appropriately added material such as hardening agent and hardening accelerator. The thermoset resin may be epoxy resin, but is not limited thereto.

With the ultraviolet curable resin, the curing step may be irradiating the resin composition with ultraviolet to cure the resin composition. The ultraviolet irradiation may be performed by a UV lamp. The resin composition may include, in addition to the resin as the main component, an appropriately added material such as polymerization initiator and polymerization accelerator. The ultraviolet curable resin may be acrylic resin, but is not limited thereto.

When finished is the curing of the resin composition, the organic EL light emitting device shown in FIG. 1 can be obtained in which the organic EL elements 10 are arranged in a plane. In view of the workability, the electric wires 14 are preferably connected before the filling step. However, they may be connected after the curing step, if they can be connected in proper positions. The organic EL light emitting device obtained by this method has superior moisture prevention property and/or superior oxygen prevention property, as well as has superior light extraction efficiency.

FIG. 2 shows an example of another embodiment of an organic EL light emitting device. Like kind elements are assigned the same reference numerals as depicted in the embodiment of FIG. 1, and detailed explanations are omitted.

The embodiment of FIG. 2 differs from the embodiment of FIG. 1 in that a functional scattering section 5 does not totally cover an end face of an optically transparent substrate 1, and is provided on part of the end face of the optically transparent substrate 1. Other structures of this embodiment are similar to those of the embodiment of FIG. 1.

In the embodiment of FIG. 2, the organic EL light emitting device having two or more organic EL elements 10 includes a lateral side functional scattering section 5a. The lateral side functional scattering section 5a is provided on an outside end face of an optically transparent substrate 1 in an organic EL element 10 that is arranged at a lateral end of the device. In the embodiment, the lateral side functional scattering section 5a is provided in a manner that part of the end face of this optically transparent substrate 1 is covered with the lateral side functional scattering section 5a. The lateral side functional scattering section 5a is adhered to a support member 15 in contact therewith and also is adhered to the part of the end face of the optically transparent substrate 1 in contact therewith. The lateral side functional scattering section 5a totally covers an end face of a plastic layer 12 and also partially covers an end face of a glass substrate 11. In this embodiment, since the lateral side functional scattering section 5a is in contact with the support member 15, a lateral side of an organic EL element 10 arranged at the lateral end of the device is occluded by the lateral side functional scattering section 5a. As a result, an outside end face of the plastic layer 12 of the organic EL element 10 arranged at the lateral end is isolated from and also is not communicated with the outside space.

In the embodiment, an inter-element functional scattering section 5b fills a gap between adjacent optically transparent substrates 1, 1 from an outside surface side. The inter-element functional scattering section 5b can be said to be in contact with an end face of an optically transparent substrate 1 at an end of the optically transparent substrate 1. In the embodiment, the inter-element functional scattering section 5b is in contact with part of an end face of the plastic layer 12. In this embodiment, the inter-element functional scattering section 5b is provided in the gap so that at least outer side of the gap compared with the plastic layer 12 in the stacking direction is filled with the inter-element functional scattering section 5b. With this configuration, since the gap between the optically transparent substrates 1, 1 is filled with the inter-element functional scattering section 5b, the inter-element space 13 is not communicated with the outside space and as a result the plastic layer 12 in the light emitting device can be isolated from the outside space. In the embodiment of FIG. 2, the resin composition is filled in the gap so as to be overflowed therefrom to an outer surface of the optically transparent substrate 1, so that the inter-element functional scattering section 5b is also formed on an outer side surface of the glass substrate 11 so as to cover the gap between the optically transparent substrates 1, 1. As a result, a larger amount of the functional scattering section 5 can be provided in a boundary part between the organic EL elements 10.

Also in the embodiment of FIG. 2, since the plastic layer 12 is not exposed outward, it is possible to prevent moisture and/or oxygen from entering the inside of the device through the plastic layer 12. It is therefore possible to suppress degradation of the element due to moisture and/or oxygen entering the inside. In addition, a guided light in the optically transparent substrate 1 is to enter the functional scattering section 5, to be scattered by the scattering bodies 6, and then to be extracted outside. It is therefore possible to increase the light extraction efficiency and also to make the gap between the elements less noticeable, and to thereby enhance the emission intensity and provide a natural light.

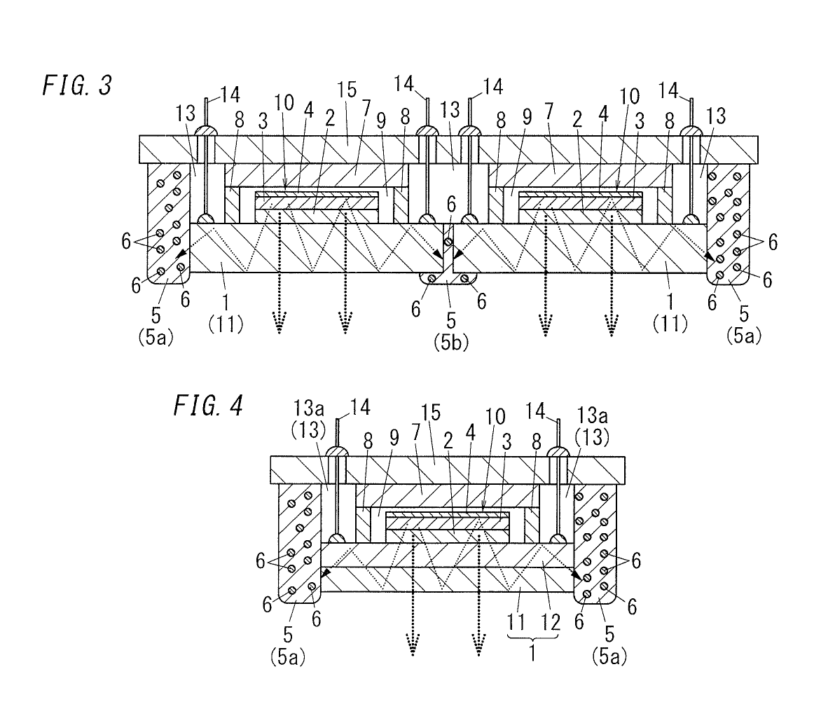

FIG. 3 shows an example of another embodiment of an organic EL light emitting device. Like kind elements are assigned the same reference numerals as depicted in the embodiment of FIG. 1, and detailed explanations are omitted.

The embodiment of FIG. 3 differs from the embodiment of FIG. 1 in that an optically transparent substrate 1 does not include a plastic layer 12 and is formed of a glass substrate 11. Other structures of this embodiment are similar to those of the embodiment of FIG. 1.

In a case where the optically transparent substrate 1 does not include the plastic layer 12, moisture- and/or oxygen does not permeate through the plastic layer 12 and does not cause a problem. However, also in this case, moisture and/or oxygen is likely to enter the inside of the element if an inter-element space 13 communicates with the outside space due to that a lateral end of the organic EL light emitting device or a gap between organic EL elements 10 is opened outside. Moisture and/or oxygen usually tends to enter the inside of the organic EL element 10 through a sealing resin member 8 or an interface of an electrode pad. On the contrary, in the embodiment, since a functional scattering section 5 is provided to enclose the inter-element space 13, the inter-element space 13 does not communicate with the outside space and it is therefore possible to prevent moisture and/or oxygen from entering inside the element. In addition, in this embodiment, since the functional scattering section 5 is provided on an end face of the optically transparent substrate 1, a guided light in the optically transparent substrate 1 can be extracted to the outside. It is therefore possible to increase the light extraction efficiency and also to make the gap between the elements less noticeable, and to thereby enhance the emission intensity and provide a natural light.

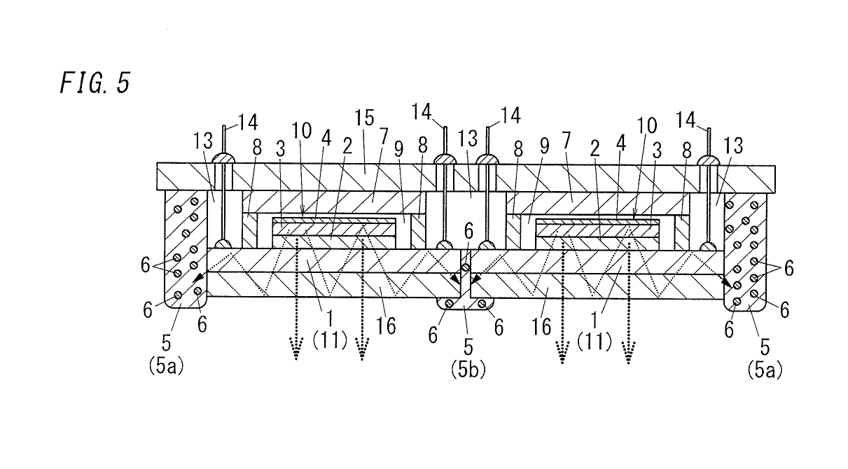

FIG. 5 shows an example of another embodiment of an organic EL light emitting device. Like kind elements are assigned the same reference numerals as depicted in the embodiment of FIG. 1, and detailed explanations are omitted.

The embodiment of FIG. 5 differs from the embodiment of FIG. 1 in that an optically transparent substrate 1 is formed of a glass substrate 11, and that an optical film 16 is adhered on an outer side surface of the glass substrate 11. Other structures of this embodiment are similar to those of the embodiment of FIG. 1.

According to the embodiment of FIG. 5, the light extraction efficiency can be increased by the optical film 16. Examples of the optical film 16 include lens-shaped film having micro lenses or pyramidal structures, and light scattering film in which fine particles are dispersed.

In the embodiment of FIG. 5, resin composition for forming a functional scattering section 5 can be cured after tiling an organic EL element(s) 10 on an optically transparent substrate 1 to which the optical film 16 is adhered. Therefore, it is possible to prepare a lot of organic EL elements 10 having the same specification in advance, to pick non-defective products from the prepared ones, and to manufacture an organic EL light emitting device using the non-defective products. As a result, this configuration makes it possible to enhance the yield of the illumination device and improve the productivity. Note that the optical film 16 may be attached to the optically transparent substrate 1 after forming the functional scattering section 5 by curing the resin composition. With this process, the optical film 16 is free from melting owing to the heat for curing the resin composition, and therefore appearance of the illumination device can be improved and yield ratio thereof can be enhanced.

The embodiments of FIGS. 2, 3, and 5 can be manufactured with the similar method to that described for the embodiment of FIG. 1. That is, the functional scattering section 5 can be formed by filling the gap between the optically transparent substrates 1, 1 of the organic EL elements 10 with the resin composition. According to the embodiments of FIGS. 1 and 2, since the communication between the inter-element space 13 and the outside space is blocked by the functional scattering section 5, it is possible to prevent moisture and/or oxygen from entering the device through the sealing resin member 6 or the electrode pad, as similar to the embodiment of FIG. 3. Note that it is more important for the embodiments of FIGS. 1 and 2 to prevent moisture and/or oxygen from entering the device through the plastic layer 12.

FIG. 4 shows an example of another embodiment of an organic EL light emitting device. Like kind elements are assigned the same reference numerals as depicted in the embodiment of FIG. 1, and detailed explanations are omitted.

The embodiment of FIG. 4 is an organic EL light emitting device that includes one organic EL element 10. That is, the organic EL light emitting device includes only one organic EL element 10, and therefore no gap is formed between elements. Therefore, all of the functional scattering section 5 is a lateral side functional scattering section 5a. Note that an inter-element space 13 is not a space among elements, but exists as a device end-space 13a.

In the embodiment of FIG. 4, the functional scattering section 5 is provided on an end face of an optically transparent substrate 1 of an organic EL element 10 so that the end face of this optically transparent substrate 1 is totally covered with the functional scattering section 5. The functional scattering section 5 is adhered to the support member 15 in contact therewith and also is adhered to the end face of the optically transparent substrate 1 in contact therewith. The functional scattering section 5 may be provided to surround the organic EL elements 10 at a lateral end of the organic EL light emitting device. Surrounded by the functional scattering section 5, an end face of a plastic layer 12 is covered at a lateral end of the optically transparent substrate 1 and the plastic layer 12 is isolated from the outside space.

Also in the embodiment of FIG. 4, since the plastic layer 12 is not exposed outward, it is possible to prevent moisture and/or oxygen from entering the inside of the device through the plastic layer 12. In addition, moisture can be blocked by a sealing resin member 8. Thus, permeation of moisture and oxygen into the sealed space 9 can be doubly blocked by the functional scattering section 5 and the sealing resin member 8. Therefore, it is possible to suppress degradation of the element due to moisture and/or oxygen entering inside. In addition, a guided light in the optically transparent substrate 1 is to enter the functional scattering section 5, to be scattered by the scattering bodies 6, and then to be extracted outside. Therefore, it is possible to increase the light extraction efficiency and to thereby enhance the emission intensity.

### REFERENCE SIGNS LIST

1 optically transparent substrate

2 first electrode

3 light emitting function layer

4 second electrode

5 functional scattering section

6 scattering body

7 protection substrate

8 sealing resin member

9 sealed space

10 organic electroluminescent element

11 glass substrate

12 plastic layer

13 inter-element space

14 electric wire

15 support base

16 optical film

1. An organic electroluminescent light emitting device comprising:
an organic electroluminescent element that comprises a first electrode with optical transparency, a light emitting function layer composed of two or more layers including a light emitting layer, and a second electrode, which are stacked on a surface of an optically transparent substrate in that order; and
a functional scattering section provided in contact with at least part of an end face of the optically transparent substrate, said functional scattering section being formed of a resin composition comprising a scattering body that has at least one of moisture absorption property and oxygen absorption property.

2. The organic electroluminescent light emitting device according to claim 1, wherein the functional scattering section contains toning dye that controls light color emitted from the end face of the optically transparent substrate.

3. The organic electroluminescent light emitting device according to claim 2, wherein the toning dye is dye for converting the light emitted from the end face of the optically transparent substrate into a white light.

4. The organic electroluminescent light emitting device according to claim 2, wherein the toning dye contains at least blue pigment.

5. The organic electroluminescent light emitting device according to claim 1, wherein
the organic electroluminescent element is provided two or more in a direction perpendicular to a stacking direction of an organic electroluminescent element, and
the functional scattering section is formed between optically transparent substrates of adjacent organic electroluminescent elements.

6. The organic electroluminescent light emitting device according to claim 1, wherein
the optically transparent substrate is composed of a glass substrate and a plastic layer formed over at least part of a surface of the glass substrate, and
the functional scattering section is in contact with an end face of the plastic layer.

7. A method for manufacturing organic electroluminescent light emitting device, comprising:
an arranging step of arranging, on a surface of a support base, two or more organic electroluminescent elements each of which comprises an optically transparent first electrode, a light emitting function layer composed of two or more layers including a light emitting layer, and a second electrode, which are stacked on a surface of an optically transparent substrate in that order;
a filling step of filling a resin composition comprising a scattering body between optically transparent substrates of adjacent organic electroluminescent elements; and
a curing step of curing the resin composition.

8. The method for manufacturing organic electroluminescent light emitting device according to claim 7, wherein the scattering body has at least one of moisture absorption property and oxygen absorption property.

9. The method for manufacturing organic electroluminescent light emitting device according to claim 7, wherein
the resin composition comprises thermoset resin, and
the curing step comprises heating the resin composition to cure the resin composition.

10. The method for manufacturing organic electroluminescent light emitting device according to claim 7, wherein
the resin composition comprises ultraviolet curable resin, and
the curing step comprises irradiating the resin composition with ultraviolet to cure the resin composition.
